(19) United States
(12) Patent Application Publication
(10) Pub. No.: US 2026/0261250 A1
(43) Pub. Date: Sep. 3, 2026

(54) ACOUSTIC WAVE DEVICE AND ACOUSTIC WAVE FILTER

(71) Applicant: Murata Manufacturing Co., Ltd., Nagaokakyo-shi (JP)

(72) Inventor: Katsuya DAIMON, Nagaokakyo-shi (JP)

(21) Appl. No.: 19/541,775

(22) Filed: Feb. 17, 2026

(30) Foreign Application Priority Data
Feb. 28, 2025 (JP) 2025-031199

(51) Int. Cl. H03H 9/02; H03H 9/13; H03H 9/205; H03H 9/60

(52) U.S. Cl. CPC H03H 9/02015; H03H 9/133; H03H 9/205; H03H 9/605

(57) ABSTRACT

In an acoustic wave device, a first acoustic wave resonator includes a first piezoelectric layer having Euler angles (ψ1, θ1, φ1), where ψ1 is [(greater than or equal to 85° and less than or equal to 95°)+180°×n (n being an integer)], θ1 is [(greater than or equal to 85° and less than or equal to 95°)+180°×n], and φ1 is [(greater than or equal to 30° and less than or equal to 140°)+180°×n], and a second acoustic wave resonator includes a second piezoelectric layer having Euler angles (ψ2, θ2, φ2), where ψ2 is [(greater than or equal to 85° and less than or equal to 95°)+180°×n], θ2 is [(greater than or equal to 85° and less than or equal to 95°)+180°×n], and φ2 is [(greater than or equal to −40° and less than or equal to 20°)+180°×n]. The first and second acoustic wave resonators are implemented as a single chip.

### CROSS REFERENCE TO RELATED APPLICATIONS

This application claims the benefit of priority to Japanese Patent Application No. 2025-031199 filed on Feb. 28, 2025. The entire contents of this application are hereby incorporated herein by reference.

### BACKGROUND OF THE INVENTION

### 1. Field of the Invention

The present invention relates to acoustic wave devices and acoustic wave filters.

### 2. Description of the Related Art

Japanese Unexamined Patent Application Publication No. 2015-073331 discloses an acoustic wave device including a rotated Y-cut piezoelectric layer and configured to excite acoustic waves of the SV and SH modes.

### SUMMARY OF THE INVENTION

The increasing capacity of mobile communications has led to a demand for acoustic wave devices configured to achieve wider-band operation.

Accordingly, example embodiments of the present invention provide acoustic wave devices and acoustic wave filters that are each configured to achieve wider-band operation.

An acoustic wave device according to an example embodiment of the present invention includes a first acoustic wave resonator and a second acoustic wave resonator electrically connected to each other. The first acoustic wave resonator includes a first piezoelectric layer having Euler angles (ψ1, θ1, φ1), and a first interdigital transducer (IDT) electrode on the first piezoelectric layer. ψ1 is [(greater than or equal to 85° and less than or equal to 95°)+180°×n (n being an integer)], θ1 is [(greater than or equal to 85° and less than or equal to 95°)+180°×n], and φ1 is [(greater than or equal to 30° and less than or equal to 140°)+180°×n]. The first piezoelectric layer has a thickness less than or equal to λ1, where λ1 is a wavelength of an acoustic wave determined by a period of electrode fingers of the first IDT electrode. The second acoustic wave resonator includes a second piezoelectric layer having Euler angles (ψ2, θ2, φ2), and a second IDT electrode disposed on the second piezoelectric layer. ψ2 is [(greater than or equal to 85° and less than or equal to 95°)+180°×n], θ2 is [(greater than or equal to 85° and less than or equal to 95°)+180°×n], and φ2 is [(greater than or equal to −40° and less than or equal to 20°)+180°×n]. The first acoustic wave resonator and the second acoustic wave resonator are implemented as a single chip.

An acoustic wave filter according to an example embodiment of the present invention includes a first input/output terminal and a second input/output terminal, one or more series resonators along a path that connects the first input/output terminal and the second input/output terminal, and one or more shunt resonators connected between the one or more series resonators and ground. At least one of the one or more series resonators is the first acoustic wave resonator mentioned above, and at least one of the one or more shunt resonators is the second acoustic wave resonator mentioned above.

Example embodiments of the present invention provide acoustic wave devices and acoustic wave filters that achieve higher-frequency and wider-band operation.

The above and other elements, features, steps, characteristics and advantages of the present invention will become more apparent from the following detailed description of the present example embodiments with reference to the attached drawings.

### BRIEF DESCRIPTION OF THE DRAWINGS

FIGS. 1A and 1B are a plan view and a cross-sectional view, respectively, of an acoustic wave device according to an example embodiment of the present invention.

FIG. 2A is a graph representing the impedance characteristics of a first acoustic wave resonator according to an example embodiment of the present invention.

FIG. 2B is a graph representing the phase characteristics of the first acoustic wave resonator according to an example embodiment of the present invention.

FIG. 3 is a graph representing the impedance characteristics of a second acoustic wave resonator according to an example embodiment of the present invention.

FIG. 4 is a graph representing the impedance characteristics of a second acoustic wave resonator according to Modification 1 of an example embodiment of the present invention.

FIG. 5 is a cross-sectional view of an acoustic wave device according to Modification 2 of an example embodiment of the present invention.

FIG. 6 is a graph representing the relationship between the third Euler angle φ and an electromechanical coupling coefficient K2 when an acoustic wave of the S0 mode and an acoustic wave of the SH0 mode propagate.

FIG. 7 is a circuit diagram of an acoustic wave filter according to an example embodiment of the present invention.

FIG. 8 illustrates, in plan view, the electrode layout of the acoustic wave filter according to an example embodiment of the present invention.

### DETAILED DESCRIPTION OF THE EXAMPLE EMBODIMENTS

Example embodiments of the present disclosure will now be described in detail below with reference to the drawings. The example embodiments described below each represent a generic or specific example. Features presented in the following example embodiments, such as numerical values, shapes, materials, components, and the positioning and connection of components, are illustrative only and not intended to be limiting of the present invention.

The drawings are schematic in nature with emphases, omissions, or proportion adjustments made as necessary to illustrate the present invention, and do not necessarily represent exact details. Accordingly, the illustrated shapes, positional relationships, and proportions may differ from the actuality. Throughout the drawings, identical reference signs are used to designate substantially identical structural features, and repetitive description will be sometimes omitted or simplified.

Terms indicative of the relationship between elements, such as “parallel” and “perpendicular”, and terms indicative of the shape of an element, such as “rectangular”, as well as numerical ranges are not intended to represent only their strict meanings but are meant to also include their substantial equivalents with a margin of error of, for example, about several percent.

A passband of an acoustic wave device or an acoustic wave filter is herein defined as the frequency band between two frequencies at which the insertion loss is about 3 dB greater than the minimum insertion loss within the passband.

With regard to the resonance characteristics of the acoustic wave devices according to example embodiments of the present disclosure, a resonant frequency and an anti-resonant frequency are derived by bringing an RF probe into contact with two input/output terminals of the acoustic wave device with no other circuit element connected to the acoustic wave device, and then measuring the reflection characteristics (impedance characteristics) with a network analyzer or the like.

As used herein, expressions such as “a major component of a material” refer to a component that constitutes more than 50% by weight of the material. The major component may be present in one of a monocrystalline state, a polycrystalline state, or an amorphous state, or in a mixture of these states.

When it is stated herein that two acoustic wave resonators are implemented as a single chip, this means that at least one of the following conditions is satisfied: (1) two acoustic wave resonators are accommodated in a single package; (2) two acoustic wave resonators are located on a common support substrate; and (3) the respective IDT electrodes of two acoustic wave resonators are located on a common piezoelectric layer.

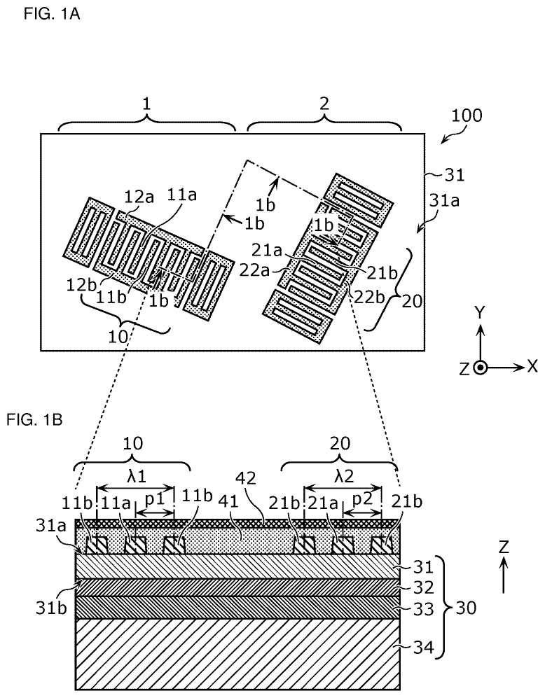

FIGS. 1A and 1B are a plan view and a cross-sectional view, respectively, of an acoustic wave device 100 according to an example embodiment of the present invention. FIG. 1A illustrates, in plan view, a major surface 31a of a piezoelectric layer 31 as seen from the positive side of the z-axis. FIG. 1B is a cross-sectional view taken along a line Ib-Ib in FIG. 1A. As illustrated in FIGS. 1A and 1B, the acoustic wave device 100 includes an acoustic wave resonator 1, and an acoustic wave resonator 2.

The acoustic wave resonator 1 is an example of a first acoustic wave resonator. The acoustic wave resonator 1 includes an IDT electrode 10, the piezoelectric layer 31, a low acoustic velocity layer 32, a high acoustic velocity layer 33, a support substrate 34, an insulating layer 41, and a dielectric film 42. The acoustic wave resonator 2 is an example of a second acoustic wave resonator. The acoustic wave resonator 2 includes an IDT electrode 20, the piezoelectric layer 31, the low acoustic velocity layer 32, the high acoustic velocity layer 33, the support substrate 34, the insulating layer 41, and the dielectric film 42. The piezoelectric layer 31, the low acoustic velocity layer 32, the high acoustic velocity layer 33, and the support substrate 34 constitute a piezoelectric substrate 30. The acoustic wave resonators 1 and 2 share the piezoelectric substrate 30, and are implemented as a single chip. The illustrations of the acoustic wave device 100 in FIGS. 1A and 1B are provided for the purpose of explaining the typical construction of the acoustic wave resonators 1 and 2 of the acoustic wave device 100, and not intended to limit features such as the number and length of the electrode fingers of each of the IDT electrodes 10 and 20 to the specific details illustrated.

The piezoelectric layer 31 is a common piezoelectric layer having Euler angles (ψc, θc, φ) and including the major surface 31a (a first major surface) and a major surface 31b (a second major surface) that are opposite to each other. ψc is [(greater than or equal to 85° and less than or equal to 95°)+180°×n], and θc is [(greater than or equal to 85° and less than or equal to 95°)+180°×n]. The piezoelectric layer 31 is made of a material including lithium niobate (LiNbO₃) or lithium niobate as its major component. That is, the piezoelectric layer 31 is made of an X-cut LiNbO₃ piezoelectric single crystal or X-cut LiNbO₃ piezoelectric ceramic material (a lithium niobate single crystal or lithium niobate ceramic material that is cut along a plane whose normal is the axis (Z-axis) defined by rotation of the X-axis by) ψc° (90°) about the Y-axis, and in which an acoustic wave propagates in the direction of the XY-plane).

The piezoelectric layer 31 has a thickness less than or equal to λ1, where λ1 is a wavelength of an acoustic wave determined by the period of the electrode fingers of the IDT electrode 10. This makes it possible for the acoustic wave resonator 1 to efficiently excite an acoustic wave of the S0 (zeroth-order S-wave) mode. From the viewpoint of ensuring crystallinity and thickness uniformity, the thickness of the piezoelectric layer 31 is desired to be greater than or equal to about 200 nm, for example.

The piezoelectric layer 31 may be made of, for example, a material including lithium tantalate (LiTaO₃) or lithium tantalate as its major component.

The Euler angles of the piezoelectric layer 31 are determined by X-ray diffraction (XRD) or other methods.

The piezoelectric layer 31 may include a first piezoelectric layer with Euler angles (ψ1, θ1, φ1), and a second piezoelectric layer with Euler angles (ψ2, θ2, φ2). The acoustic wave resonator 1 includes the first piezoelectric layer, the acoustic wave resonator 2 includes the second piezoelectric layer, and the first piezoelectric layer and the second piezoelectric layer are both disposed on the low acoustic velocity layer 32. The IDT electrode 10 is disposed on the first piezoelectric layer, and the IDT electrode 20 is disposed on the second piezoelectric layer. ψ1 is [(greater than or equal to 85° and less than or equal to 95°)+180°×n (n being an integer)], θ1 is [(greater than or equal to 85° and less than or equal to 95°)+180°×n], and φ1 is [(greater than or equal to 30° and less than or equal to 140°)+180°×n]. Further, ψ2 is [(greater than or equal to 85° and less than or equal to 95°)+180°×n], θ2 is [(greater than or equal to 85° and less than or equal to 95°)+180°×n], and φ2 is [(greater than or equal to −40° and less than or equal to 20°)+180°×n]. The first piezoelectric layer has a thickness less than or equal to λ1.

In the acoustic wave device 100 according to the present example embodiment, the piezoelectric layer 31 is a single common piezoelectric layer including the first and second piezoelectric layers that satisfy the relationship ψ1=ψ2 and θ1=θ2.

The IDT electrode 10 is an example of a first IDT electrode, and disposed on the major surface 31a of the piezoelectric layer 31. As illustrated in FIG. 1A, the IDT electrode 10 includes a plurality of electrode fingers 11a, a plurality of electrode fingers 11b, a busbar electrode 12a, and a busbar electrode 12b.

The electrode fingers 11a are arranged in parallel or substantially in parallel to each other. The electrode fingers 11b are arranged in parallel or substantially in parallel to each other. The electrode fingers 11a and the electrode fingers 11b are arranged in parallel or substantially in parallel to each other so as to interdigitate. The busbar electrode 12a is disposed so as to interconnect respective one ends of the electrode fingers 11a. The busbar electrode 12a extends in a direction intersecting a direction in which the electrode fingers 11a extend. The busbar electrode 12b is disposed so as to interconnect respective one ends of the electrode fingers 11b. The busbar electrode 12b extends in a direction intersecting a direction in which the electrode fingers 11b extend. The busbar electrode 12a and the busbar electrode 12b are disposed opposite from each other across the electrode fingers 11a and the electrode fingers 11b. The other end of each of the electrode fingers 11a faces the busbar electrode 12b, and the other end of each of the electrode fingers 11b faces the busbar electrode 12a. A reflector electrode is disposed at each side of the IDT electrode 10 in a direction perpendicular to the direction in which the electrode fingers 11a and 11b extend, such that the reflector electrode is adjacent to the IDT electrode 10. Alternatively, no reflector electrode may be disposed at each side of the IDT electrode 10.

The IDT electrode 10 is disposed such that the direction perpendicular to the electrode fingers 11a and 11b on the major surface 31a is inclined by the angle φ1 [(greater than or equal to 30° and less than or equal to 140°)+180°×n] with respect to the X-axis.

The IDT electrode 20 is an example of a second IDT electrode, and disposed on the major surface 31a of the piezoelectric layer 31. As illustrated in FIG. 1A, the IDT electrode 20 includes a plurality of electrode fingers 21a, a plurality of electrode fingers 21b, a busbar electrode 22a, and a busbar electrode 22b.

The electrode fingers 21a are arranged in parallel or substantially in parallel to each other. The electrode fingers 21b are arranged in parallel or substantially in parallel to each other. The electrode fingers 21a and the electrode fingers 21b are arranged in parallel or substantially in parallel to each other so as to interdigitate. The busbar electrode 22a is disposed so as to interconnect respective one ends of the electrode fingers 21a. The busbar electrode 22a extends in a direction intersecting a direction in which the electrode fingers 21a extend. The busbar electrode 22b is disposed so as to interconnect respective one ends of the electrode fingers 21b. The busbar electrode 22b extends in a direction intersecting a direction in which the electrode fingers 21b extend. The busbar electrode 22a and the busbar electrode 22b are disposed opposite from each other across the electrode fingers 21a and the electrode fingers 21b. The other end of each of the electrode fingers 21a faces the busbar electrode 22b, and the other end of each of the electrode fingers 21b faces the busbar electrode 22a. A reflector electrode is disposed at each side of the IDT electrode 20 in a direction perpendicular to the direction in which the electrode fingers 21a and 21b extend, such that the reflector electrode is adjacent to the IDT electrode 20. Alternatively, no reflector electrode may be disposed at each side of the IDT electrode 20.

The IDT electrode 20 is disposed such that the direction perpendicular to the electrode fingers 21a and 21b on the major surface 31a is inclined by the angle φ2 [(greater than or equal to −40° and less than or equal to 20°)+180°×n] with respect to the X-axis.

The IDT electrode 10 and the IDT electrode 20 are electrically connected.

When “t” denotes the film thickness of the electrode fingers of the IDT electrode 10, and “d” denotes the density of the IDT electrode 10, (t/λ1)×d is equal to or greater than about 8.94 (g/m³), for example. This configuration makes it possible to reduce, in the acoustic wave resonator 1, leakage of an acoustic wave of the so mode toward the support substrate 34 even when the piezoelectric layer 31 of an X-cut type is used.

Each of the IDT electrodes 10 and 20 is a multilayer structure including a plurality of metal layers. Desirably, at least one of the metal layers of the IDT electrode 10 includes a high-density metal, examples of which include platinum (Pt), gold (Au), copper (Cu), and tungsten (W).

The electrode parameters of the IDT electrodes 10 and 20 will now be described. Although the following description is directed to the electrode parameters of the IDT electrode 10, the electrode parameters of the IDT electrode 20 are defined in a similar manner.

The wavelength λ1 of the IDT electrode 10 is a unit of length defined by the repetition period of the electrode fingers 11a or 11b. If the spacing between adjacent electrode fingers of the IDT electrode 10 is not constant, the wavelength λ1 of the IDT electrode 10 is defined by an average wavelength λ1_{AVE} of the IDT electrode 10. The average wavelength λ1_{AVE} of the IDT electrode 10 is defined as 2×Di/(Ni−1), where Ni is the total number of the electrode fingers 11a and 11b included in the IDT electrode 10, and Di is the center-to-center distance between an electrode finger located at one end of the IDT electrode 10 in the direction of acoustic wave propagation and an electrode finger located at the other end of the IDT electrode 10 in the direction of acoustic wave propagation.

If the IDT electrode 10 includes so-called dummy electrodes, then the average wavelength λ1_{AVE} is calculated by excluding the number of dummy electrodes from the total number Ni of electrode fingers and by excluding, from the center-to-center distance Di, the line width L of each dummy electrode and one of two spaces (space widths S) adjacent to the dummy electrode. Dummy electrodes include a floating dummy electrode, a polarity-reversed electrode, and a filled electrode. A floating dummy electrode refers to an electrode finger that is not connected to either of the two opposite busbar electrodes, and that is arranged in parallel or substantially in parallel to an electrode finger connected to one of the two busbar electrodes. A polarity-reversed electrode refers to an electrode finger that is connected to the same busbar electrode to which two electrode fingers adjacent to the opposite sides of the electrode finger are connected, and that is arranged in parallel or substantially in parallel to the two electrode fingers adjacent to the opposite sides of the electrode finger. A filled electrode refers to an electrode finger that has an electrode finger width equal to or greater than twice the average electrode finger width of the electrode fingers excluding the electrode finger, and that is arranged in parallel or substantially in parallel to the electrode fingers excluding the electrode finger.

The wavelength λ2 of the IDT electrode 20 is a unit of length defined by the repetition period of the electrode fingers 21a or 21b. The wavelength λ2 of the IDT electrode 20 is defined in a manner similar to the wavelength λ1 of the IDT electrode 10.

The wavelength λ1 of the IDT electrode 10 and the wavelength λ2 of the IDT electrode 20 can be determined through measurement of the line width and the space width by observing, with a scanning electron microscope (SEM), a scanning transmission electron microscope (STEM), or a transmission electron microscope (TEM), a plan view of a major surface of the piezoelectric substrate 30 on which the IDT electrode 10 exists, and/or by observing a cross-section taken in a direction perpendicular to the direction in which the electrode fingers 11a and 11b (the electrode fingers 21a and 21b) extend.

The support substrate 34 is a common support substrate disposed at the same side of the acoustic wave device 100 as the major surface 31b of the piezoelectric layer 31 to support the piezoelectric layer 31 and the IDT electrodes 10 and 20. The support substrate 34 is made of, for example, a non-oxide material, which may be silicon (Si), silicon carbide (SiC), or a material including such a material as its major component. Since silicon and silicon carbide have high thermal conductivity, using such a material for the support substrate 34 allows for improved heat dissipation of the acoustic wave device 100.

The low acoustic velocity layer 32 is a first common dielectric film that is between the piezoelectric layer 31 and the support substrate 34, and in which a bulk wave propagates at an acoustic velocity lower than the acoustic velocity at which a bulk wave propagates in the piezoelectric layer 31. An example of the material of the low acoustic velocity layer 32 may be silicon oxide (e.g., silicon dioxide), or a material including silicon oxide as its major component.

Another example of the material of the low acoustic velocity layer 32 may be a dielectric such as glass, silicon oxide, silicon oxynitride, lithium oxide, tantalum oxide, or a compound with fluorine, carbon, or boron added to silicon oxide, or a material including any of the above-mentioned materials as its major component.

The high acoustic velocity layer 33 is a second common dielectric film that is between the low acoustic velocity layer 32 and the support substrate 34, and in which a bulk wave propagates at an acoustic velocity higher than the acoustic velocity at which a bulk wave propagates in the piezoelectric layer 31. An example of the material of the high acoustic velocity layer 33 may be silicon nitride (SiN), or a material including silicon nitride as its major component.

An example of the material of the high acoustic velocity layer 33 may be a ceramic material such as aluminum nitride (AlN), silicon nitride (SiN), zirconia, cordierite, mullite, steatite, forsterite, spinel, or sialon, a dielectric material such as aluminum oxide, silicon oxynitride, diamond-like carbon (DLC), or diamond, or a material including any of the above-mentioned materials as its major component. The spinel includes an aluminum compound containing oxygen and one or more elements selected from elements such as Mg, Fe, Zn, and Mn. Examples of the spinel may include MgAl₂O₄, FeAl₂O₄, ZnAl₂O₄, and MnAl₂O₄.

The low acoustic velocity layer 32 and the high acoustic velocity layer 33 constitute a common dielectric layer, and are between the piezoelectric layer 31 and the support substrate 34. The common dielectric layer includes the low acoustic velocity layer 32 and the high acoustic velocity layer 33 that are disposed in a direction from the piezoelectric layer 31 toward the support substrate 34.

The thickness of the low acoustic velocity layer 32 is, for example, greater than about 0.15×λ1, and less than 0.25×λ1. The thickness of the high acoustic velocity layer 33 is, for example, greater than about 0.15×λ1, and less than 1×λ1. Setting at least one of the thickness of the low acoustic velocity layer 32 or the thickness of the high acoustic velocity layer 33 to be within the above-mentioned range makes it possible to reduce spurious signals of unwanted modes appearing at frequencies higher than the resonant frequency band of the acoustic wave resonator 1, and reduce spurious signals of unwanted modes appearing at frequencies lower than the resonant frequency band of the acoustic wave resonator 2.

The acoustic wave device 100 need not necessarily include the low acoustic velocity layer 32 and the high acoustic velocity layer 33. In this case, the support substrate 34 may serve as a high acoustic velocity layer in which a bulk wave propagates at an acoustic velocity higher than the acoustic velocity at which a bulk wave propagates in the piezoelectric layer 31. This makes it possible to reduce leakage, toward the support substrate 34, of an acoustic wave propagating in the piezoelectric layer 31.

In one configuration, the low acoustic velocity layer 32 may include a first dielectric film and a third dielectric film, the acoustic wave resonator 1 may include the support substrate 34, the high acoustic velocity layer 33, the first dielectric film, the first piezoelectric layer, and the IDT electrode 10, and the acoustic wave resonator 2 may include the support substrate 34, the high acoustic velocity layer 33, the third dielectric film, the second piezoelectric layer, and the IDT electrode 20.

In one configuration, the high acoustic velocity layer 33 may include a second dielectric film and a fourth dielectric film, the acoustic wave resonator 1 may include the support substrate 34, the second dielectric film, the first dielectric film, the first piezoelectric layer, and the IDT electrode 10, and the acoustic wave resonator 2 may include the support substrate 34, the fourth dielectric film, the third dielectric film, the second piezoelectric layer, and the IDT electrode 20.

In one configuration, the support substrate 34 may include a first support substrate and a second support substrate, the acoustic wave resonator 1 may include the first support substrate, the second dielectric film, the first dielectric film, the first piezoelectric layer, and the IDT electrode 10, and the acoustic wave resonator 2 may include the second support substrate, the fourth dielectric film, the third dielectric film, the second piezoelectric layer, and the IDT electrode 20. In this case, the acoustic wave resonators 1 and 2 are implemented as a single chip by being accommodated in a common package.

The insulating layer 41 is disposed so as to cover the IDT electrodes 10 and 20. The insulating layer 41 includes, for example, silicon dioxide (SiO₂) as its major component. This makes it possible to reduce spurious signals. The dielectric film 42 is disposed so as to cover the insulating layer 41. The dielectric film 42 is, for example, a layer in which a bulk wave propagates at an acoustic velocity higher than the acoustic velocity at which a bulk wave propagates in the piezoelectric layer 31. The insulating layer 41 and the dielectric film 42 need not necessarily be included in the acoustic wave device 100.

Table 1 presents various parameters of the acoustic wave device 100 according to the present example embodiment. The parameters presented in Table 1 are for illustrative purposes only and not intended to limit the configuration of the acoustic wave device 100 to the parameters presented in Table 1.

TABLE 1

| | | Acoustic wave | | | Acoustic wave |
|---|---|---|---|---|---|
| | | resonator 1 | | | resonator 2 |
| IDT electrode | Film thickness T (nm) | 145 | Fifth layer | 10(Ti) | ← |
| | | | Fourth layer | 100(AlCu) | ← |
| | | | Third layer | 10(Ti) | ← |
| | | | Second layer | 15(Pt) | ← |
| | | | First layer | 10(NiCr) | |

| | | | |
|---|---|---|---|
| | Wavelength λ (μm) | 1.1 | 1.25 |
| | Duty | 0.5 | ← |
| Piezoelectric | Material | LiNbO₃ | ← |
| layer 31 | Thickness (nm) | 230 | ← |
| | Euler angle ψ (°) | 90 | ← |
| | Euler angle θ (°) | 90 | ← |
| | Euler angle φ (°) | −18 | 52 |
| Low acoustic | Material | SiO₂ | ← |
| velocity layer 32 | Thickness (nm) | 30 | ← |
| High acoustic | Material | SiN | ← |
| velocity layer 33 | Thickness (nm) | 210 | ← |
| Support | Material | Si | ← |
| substrate 34 | Thickness (μm) | 10 | ← |

As presented in Table 1, the acoustic wave resonators 1 and 2 share components except for the IDT electrodes 10 and 20, and differ from each other only in terms of the respective wavelengths of the IDT electrodes 10 and 20 and the Euler angle φ of the piezoelectric layer 31.

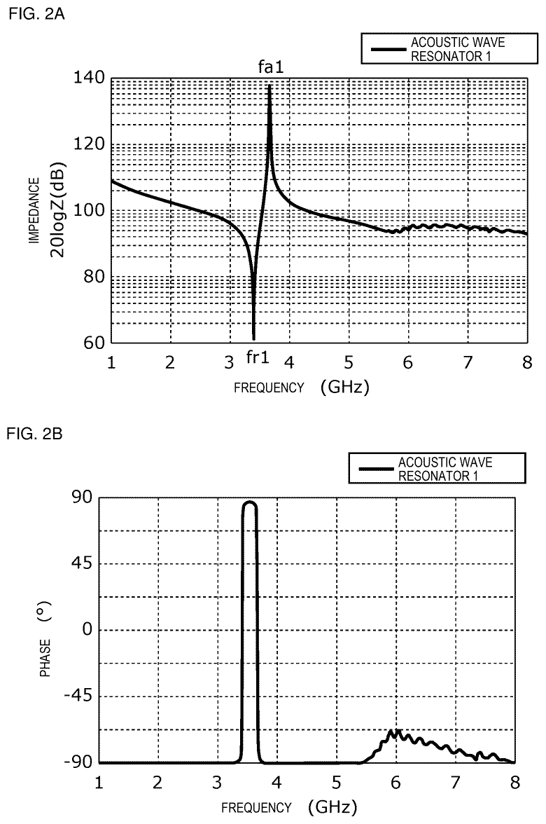

FIG. 2A is a graph representing the impedance characteristics of the acoustic wave resonator 1 according to the present example embodiment. FIG. 2B is a graph representing the phase characteristics of the acoustic wave resonator 1 according to the present example embodiment. FIGS. 2A and 2B respectively illustrate the impedance and phase characteristics of the acoustic wave resonator 1 alone. As illustrated in FIG. 2A, the acoustic wave resonator 1 has a resonant frequency fr1 at which the acoustic wave resonator 1 has a minimum impedance, and an anti-resonant frequency fa1 at which the acoustic wave resonator 1 has a maximum impedance. The impedance ratio between the resonant frequency fr1 and the anti-resonant frequency fa1 is greater than or equal to about 70 dB, for example, and the acoustic wave resonator 1 thus has a high Q-factor. Each of the resonant frequency fr1 and the anti-resonant frequency fa1 is due to an excitation signal resulting from the S0-mode acoustic wave. Further, as illustrated in FIG. 2B, the phase of the excitation signal in the resonant frequency band reaches nearly 90°, which indicates high strength of the excitation signal resulting from the S0-mode acoustic wave. In contrast, at frequencies higher than the resonant frequency band, the phase is less than or equal to −60°, for example, which indicates suppression of unwanted waves of higher-order modes.

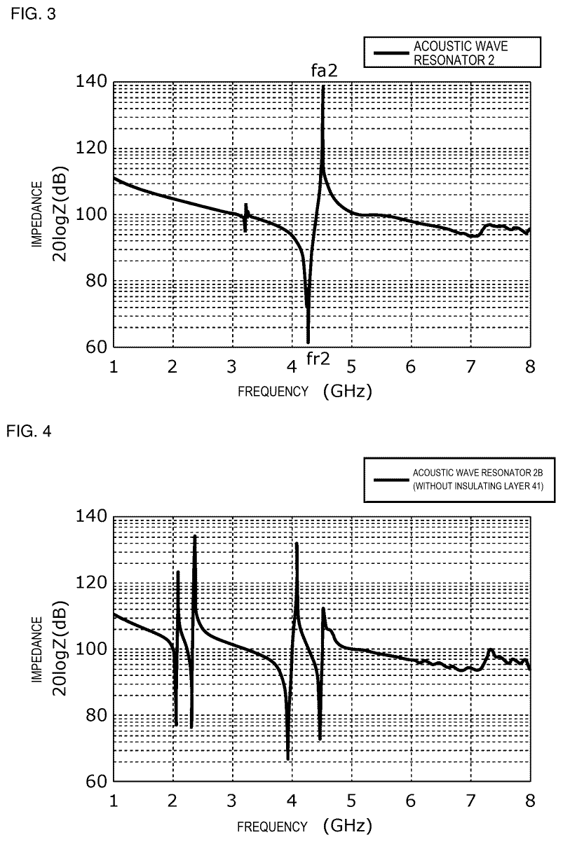

FIG. 3 is a graph representing the impedance characteristics of the acoustic wave resonator 2 according to the present example embodiment. FIG. 3 illustrates the impedance characteristics of the acoustic wave resonator 2 alone. As illustrated in the figure, the acoustic wave resonator 2 has a resonant frequency fr2 at which the acoustic wave resonator 2 has a minimum impedance, and an anti-resonant frequency fa2 at which the acoustic wave resonator 2 has a maximum impedance. Each of the resonant frequency fr2 and the anti-resonant frequency fa2 is due to an excitation signal resulting from an acoustic wave of the SH0 (zeroth-order SH wave) mode. The impedance ratio between the resonant frequency fr2 and the anti-resonant frequency fa2 is greater than or equal to about 70 dB, for example, and the acoustic wave resonator 2 thus has a high Q-factor.

In the acoustic wave device 100 according to the present example embodiment, the resonance characteristics of the acoustic wave resonators 1 and 2 change depending on the presence or absence of the insulating layer 41. FIG. 4 is a graph representing the impedance characteristics of an acoustic wave resonator 2B according to Modification 1 of the present example embodiment. The acoustic wave resonator 2B according to Modification 1 differs from the acoustic wave resonator 2 according to the present example embodiment only in that the insulating layer 41 and the dielectric film 42 are not provided.

A comparison between the resonance characteristics of the acoustic wave resonator 2 in FIG. 3 and the resonance characteristics of the acoustic wave resonator 2B in FIG. 4 reveals that the resonance characteristics of the acoustic wave resonator 2B are observed to have a plurality of resonance points and a plurality of anti-resonance points, which indicates the presence of a plurality of spurious signals resulting from the resonances of acoustic waves other than the SH0-mode acoustic wave. That is, the presence of the insulating layer 41 makes it possible to reduce spurious signals resulting from the resonances of acoustic waves other than the acoustic wave of the principal mode.

The above-mentioned configuration of the acoustic wave device 100 allows the acoustic wave resonator 1 to utilize the S0 mode, which is a high acoustic velocity mode, as its principal mode, and allows the acoustic wave resonator 2 to utilize the SH0 mode, which is a low acoustic velocity mode, as its principal mode. Further, the acoustic wave resonators 1 and 2 are electrically connected, and implemented as a single chip by use of the common X-cut piezoelectric layer 31, the common dielectric film, and the common support substrate. This makes it possible to provide the acoustic wave device 100 that is compact and has a wide resonant frequency band.

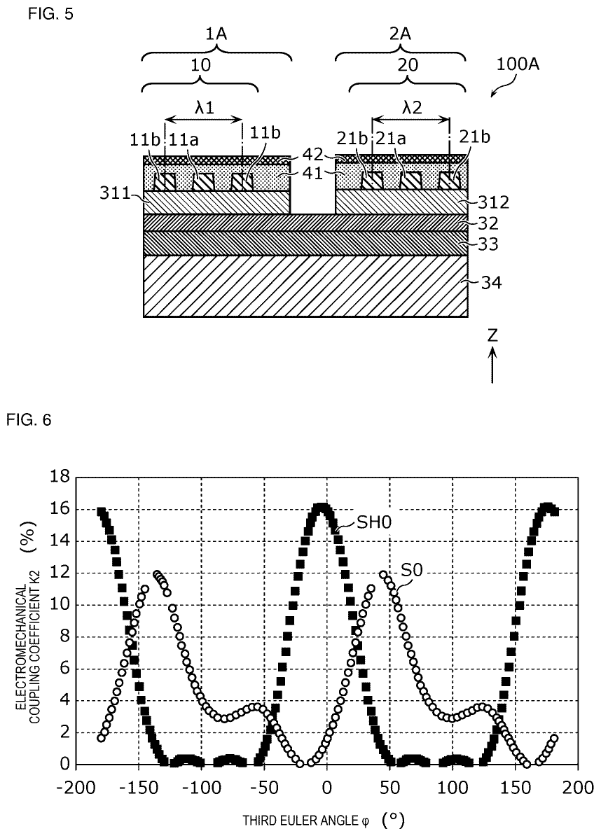

FIG. 5 is a cross-sectional view of an acoustic wave device 100A according to Modification 2 of the present example embodiment. In plan view, the acoustic wave device 100A according to Modification 2 differs from the acoustic wave device 100 according to the present example embodiment in FIG. 1A only in the presence of a cavity located between the acoustic wave resonator 1 and the acoustic wave resonator 2 and extending between the dielectric film 42 and the upper surface of the low acoustic velocity layer 32. FIG. 5 is a cross-sectional view of the acoustic wave device 100A taken along the line Ib-Ib, with the plan view of FIG. 1A regarded as a plan view of the acoustic wave device 100A.

As illustrated in FIG. 5, the acoustic wave device 100A includes an acoustic wave resonator 1A, and an acoustic wave resonator 2A. The acoustic wave device 100A according to Modification 2 differs from the acoustic wave device 100 according to the present example embodiment in the configuration of the piezoelectric substrate of each of the acoustic wave resonators 1A and 2A. Accordingly, with regard to the acoustic wave device 100A according to Modification 2, its structural features similar to those of the acoustic wave device 100 according to the present example embodiment will not be described in further detail, and the following description will focus mainly on structural features different from those of the acoustic wave device 100.

The acoustic wave resonator 1A is an example of the first acoustic wave resonator. The acoustic wave resonator 1A includes the IDT electrode 10, a piezoelectric layer 311, the low acoustic velocity layer 32, the high acoustic velocity layer 33, the support substrate 34, the insulating layer 41, and the dielectric film 42. The acoustic wave resonator 2A is an example of the second acoustic wave resonator. The acoustic wave resonator 2A includes the IDT electrode 20, a piezoelectric layer 312, the low acoustic velocity layer 32, the high acoustic velocity layer 33, the support substrate 34, the insulating layer 41, and the dielectric film 42. The acoustic wave resonators 1A and 2A share the low acoustic velocity layer 32, the high acoustic velocity layer 33, and the support substrate 34, and are implemented as a single chip.

The piezoelectric layer 311 is an example of the first piezoelectric layer. The piezoelectric layer 311 includes a major surface 311a (a third major surface) and a major surface 311b (a fourth major surface) that are opposite to each other, and has Euler angles (ψ1, θ1, φ1). ψ1 is [(greater than or equal to 85° and less than or equal to 95°)+180°×n (n being an integer)], θ1 is [(greater than or equal to 85° and less than or equal to 95°)+180°×n], and φ1 is [(greater than or equal to 30° and less than or equal to 140°)+180°×n].

The piezoelectric layer 311 has a thickness less than or equal to 1×λ1, where λ1 is a wavelength of an acoustic wave determined by the period of the electrode fingers of the IDT electrode 10. This makes it possible for the acoustic wave resonator 1A to efficiently excite an acoustic wave of the S0 mode. From the viewpoint of ensuring crystallinity and thickness uniformity, the thickness of the piezoelectric layer 311 is desired to be greater than or equal to about 200 nm, for example.

The IDT electrode 10 is an example of the first IDT electrode, and disposed on the major surface 311a of the piezoelectric layer 311.

The low acoustic velocity layer 32 is an example of the first dielectric film. The low acoustic velocity layer 32 is a layer that is between the piezoelectric layer 311 and the support substrate 34, and in which a bulk wave propagates at an acoustic velocity lower than the acoustic velocity at which a bulk wave propagates in the piezoelectric layer 311. The high acoustic velocity layer 33 is an example of the second dielectric film. The high acoustic velocity layer 33 is a layer that is between the low acoustic velocity layer 32 and the support substrate 34, and in which a bulk wave propagates at an acoustic velocity higher than the acoustic velocity at which a bulk wave propagates in the piezoelectric layer 311. The low acoustic velocity layer 32 and the high acoustic velocity layer 33 are an example of a first dielectric layer.

The piezoelectric layer 312 is an example of the second piezoelectric layer. The piezoelectric layer 312 includes a major surface 312a (a fifth major surface) and a major surface 312b (a sixth major surface) that are opposite to each other, and has Euler angles (ψ2, θ2, φ2). ψ2 is [(greater than or equal to 85° and less than or equal to 95°)+180°×n], θ2 is [(greater than or equal to 85° and less than or equal to 95°)+180°×n], and φ2 is [(greater than or equal to −40° and less than or equal to 20°)+180°×n].

The piezoelectric layers 311 and 312 are made of, for example, LiNbO₃ or a material including LiNbO₃ as its major component. Alternatively, the piezoelectric layers 311 and 312 may be made of, for example, LiTaO₃ or a material including LiTaO₃ as its major component.

The IDT electrode 20 is an example of the second IDT electrode, and disposed on the major surface 312a of the piezoelectric layer 312.

The low acoustic velocity layer 32 is an example of the third dielectric film. The low acoustic velocity layer 32 is a layer that is between the piezoelectric layer 312 and the support substrate 34, and in which a bulk wave propagates at an acoustic velocity lower than the acoustic velocity at which a bulk wave propagates in the piezoelectric layer 312. The high acoustic velocity layer 33 is an example of the fourth dielectric film. The high acoustic velocity layer 33 is a layer that is between the low acoustic velocity layer 32 and the support substrate 34, and in which a bulk wave propagates at an acoustic velocity higher than the acoustic velocity at which a bulk wave propagates in the piezoelectric layer 312. The low acoustic velocity layer 32 and the high acoustic velocity layer 33 are an example of a second dielectric layer.

The support substrate 34 is an example of the first support substrate, and disposed at the same side of the acoustic wave device 100A as the major surface 311b of the piezoelectric layer 311. The support substrate 34 is an example of the second support substrate, and disposed at the same side of the acoustic wave device 100A as the major surface 312b of the piezoelectric layer 312. According to Modification 2, the support substrate 34 is a common support substrate disposed at the same side of the acoustic wave device 100A as the major surface 311b of the piezoelectric layer 311 and the major surface 312b of the piezoelectric layer 312.

The above-mentioned configuration of the acoustic wave device 100A allows the acoustic wave resonator 1A to utilize the so mode, which is a high acoustic velocity mode, as its principal mode, and allows the acoustic wave resonator 2A to utilize the SH0 mode, which is a low acoustic velocity mode, as its principal mode. The acoustic wave resonators 1A and 2A are electrically connected, and implemented as a single chip by use of the low acoustic velocity layer 32, the high acoustic velocity layer 33, and the support substrate 34, which are common to the acoustic wave resonators 1A and 2A. This makes it possible to provide the acoustic wave device 100A that is compact and has a wide resonant frequency band.

In the acoustic wave device 100A according to Modification 2, the first dielectric film included in the acoustic wave resonator 1A (the first acoustic wave resonator), and the third dielectric film included in the acoustic wave resonator 2A (the second acoustic wave resonator) may be separated from each other. Further, the second dielectric film included in the acoustic wave resonator 1A (the first acoustic wave resonator), and the fourth dielectric film included in the acoustic wave resonator 2A (the second acoustic wave resonator) may be separated from each other.

In the acoustic wave device 100A according to Modification 2, the first support substrate included in the acoustic wave resonator 1A (the first acoustic wave resonator), and the second support substrate included in the acoustic wave resonator 2A (the second acoustic wave resonator) may be separated from each other. In this case, the first acoustic wave resonator and the second acoustic wave resonator are accommodated in a single package. In this case as well, the acoustic wave device 100A is implemented as a single chip. This makes it possible to provide the acoustic wave device 100A that is compact and has a wide resonant frequency band.

Optimization of the Euler angles of the piezoelectric layer 31 in the acoustic wave device 100 according to the present example embodiment will now be described.

FIG. 6 is a graph representing the relationship between Euler angle the φ of the piezoelectric layer 31 and an electromechanical coupling coefficient K2 (to be sometimes denoted simply as K2 hereinafter) when an acoustic wave of the S0 mode and an acoustic wave of the SH0 mode propagate. It is appreciated from the figure that the Euler angle φ at which K2 of the so mode is greater than K2 of the SH0 mode is [(greater than or equal to 30° and less than or equal to 140°)+180°×n]. Further, the Euler angle φ at which K2 of the SH0 mode is greater than K2 of the so mode is [(greater than or equal to −40° and less than or equal to 20°)+180°×n].

Accordingly, setting the Euler angle φ1 of the acoustic wave resonator 1 to be [(greater than or equal to 30° and less than or equal to 140°)+180°×n] allows the acoustic wave resonator 1 to utilize the S0 mode as its principal mode. Setting the Euler angle φ2 of the acoustic wave resonator 2 to be [(greater than or equal to −40° and less than or equal to 20°)+180°×n] allows the acoustic wave resonator 2 to utilize the SH0 mode as its principal mode.

It is appreciated from FIG. 6 that the Euler angle φ at which K2 of the S0 mode is greater than or equal to about 4% and K2 of the SH0 mode is less than or equal to about 28, for example, is [(greater than or equal to 50° and less than or equal to 70°)+180°×n]. The Euler angle φ at which K2 of the SH0 mode is greater than or equal to about 48 and K2 of the S0 mode is less than or equal to about 28, for example, is [(greater than or equal to −40° and less than or equal to 0°)+180°×n].

Accordingly, setting the Euler angle φ1 of the acoustic wave resonator 1 to be [(greater than or equal to 50° and less than or equal to 70°)+180°×n] allows the acoustic wave resonator 1 to have a large signal strength ratio between the S0 mode, which is its principal mode, and the SH0 mode. Further, setting the Euler angle φ2 of the acoustic wave resonator 2 to be [(greater than or equal to −40° and less than or equal to 0°)+180°×n] allows the acoustic wave resonator 2 to have a large signal strength ratio between the SH0 mode, which is its principal mode, and the S0 mode.

The circuit configuration of and electrode arrangement in an acoustic wave filter 200 that uses the acoustic wave resonators 1 and 2 according to the present example embodiment will now be described.

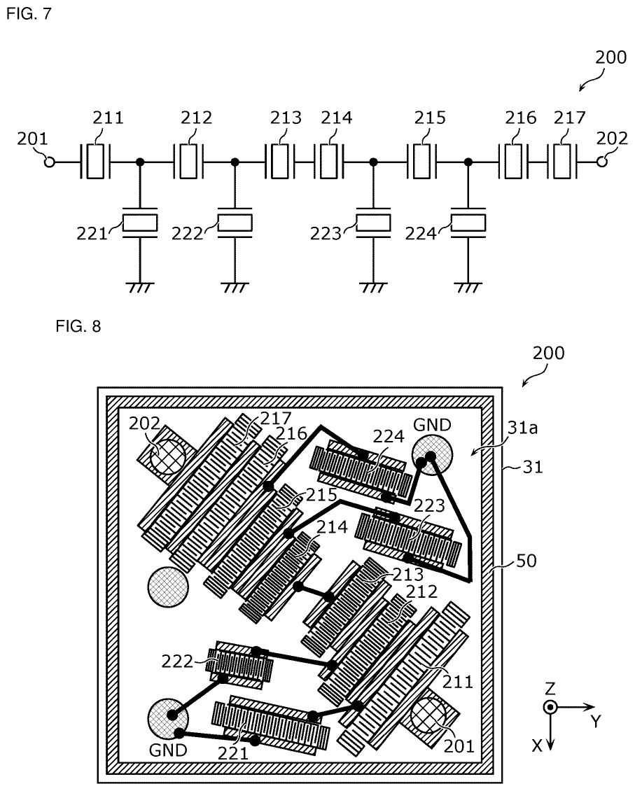

FIG. 7 is a circuit diagram of the acoustic wave filter 200 according to the present example embodiment. As illustrated in the figure, the acoustic wave filter 200 includes input/output terminals 201 and 202, series resonators 211, 212, 213, 214, 215, 216, and 217, and shunt resonators 221, 222, 223, and 224.

The series resonators 211 to 217 are disposed in a series path that connects the input/output terminal 201 (a first input/output terminal) and the input/output terminal 202 (a second input/output terminal). The shunt resonators 221 to 224 are each connected between the series path and ground. The series resonators 213 and 214 are split resonators that are connected in series. The series resonators 216 and 217 are split resonators that are connected in series.

Due to the configuration mentioned above, the acoustic wave filter 200 is implemented as a ladder filter including acoustic wave resonators. It may be sufficient that the acoustic wave filter 200 according to the present example embodiment includes one or more series resonators and one or more shunt resonators.

In this regard, each of the series resonators 211 to 217 is the acoustic wave resonator 1 according to the present example embodiment, and each of the shunt resonators 221 to 224 is the acoustic wave resonator 2 according to the present example embodiment.

The above-mentioned configuration of the acoustic wave filter 200 allows each of the series resonators 211 to 217 to utilize the S0 mode, which is a high acoustic velocity mode, as its principal mode, and allows each of the shunt resonators 221 to 224 to utilize the SH0 mode, which is a low acoustic velocity mode, as its principal mode. This makes it possible to provide the acoustic wave filter 200 having a wide passband.

FIG. 8 illustrates, in plan view, the electrode layout of the acoustic wave filter 200 according to the present example embodiment. The acoustic wave filter 200 includes the piezoelectric substrate 30 (only the piezoelectric layer 31 is illustrated) of the acoustic wave device 100 according to the present example embodiment, the respective IDT electrodes of the series resonators 211 to 217 (which each correspond to the IDT electrode 10 of the acoustic wave device 100), the respective IDT electrodes of the shunt resonators 221 to 224 (which each correspond to the IDT electrode 20 of the acoustic wave device 100), the insulating layer 41 (not illustrated), the dielectric film 42 (not illustrated), the input/output terminals 201 and 202, and a frame 50.

The IDT electrodes are disposed on the major surface 31a of the common piezoelectric layer 31. The IDT electrode of each of the series resonators 211 to 217 is disposed such that a direction perpendicular to its electrode fingers on the major surface 31a is inclined by the angle φ1 [(greater than or equal to 30° and less than or equal to 140°)+180°×n] with respect to the X-axis. The IDT electrode of each of the shunt resonators 221 to 224 is disposed such that a direction perpendicular to its electrode fingers on the major surface 31a is inclined by the angle φ2 [(greater than or equal to −40° and less than or equal to 20°)+180°×n] with respect to the X-axis.

The above-mentioned configuration of the acoustic wave filter 200 allows each of the series resonators 211 to 217 to utilize the so mode, which is a high acoustic velocity mode, as its principal mode, and allows each of the shunt resonators 221 to 224 to utilize the SH0 mode, which is a low acoustic velocity mode, as its principal mode. Further, the series resonators 211 to 217 and the shunt resonators 221 to 224 are electrically connected and implemented as a single chip. This makes it possible to provide the acoustic wave filter 200 that is compact and has a wide passband.

It may be sufficient that in the acoustic wave filter 200, the IDT electrode of at least one of the series resonators 211 to 217 is inclined by the angle φ1 [(greater than or equal to 30° and less than or equal to 140°)+180°×n] with respect to the X-axis, and that the IDT electrode of at least one of the shunt resonators 221 to 224 is inclined by the φ2 [(greater than or equal to −40° and less than or equal to 20°)+180°×n] with respect to the X-axis.

As described above, the acoustic wave device 100 according to the present example embodiment includes the acoustic wave resonators 1 and 2 that are electrically connected to each other. The acoustic wave resonator 1 includes the first piezoelectric layer having Euler Angles (ψ1, θ1, φ1), and the IDT electrode 10 disposed on the first piezoelectric layer. ψ1 is [(greater than or equal to 85° and less than or equal to 95°)+180°×n (n being an integer)], φ1 is [(greater than or equal to 85° and less than or equal to 95°)+180°×n], and φ1 is [(greater than or equal to 30° and less than or equal to 140°)+180°×n]. The first piezoelectric layer has a thickness less than or equal to 1×λ1, where λ1 is a wavelength of an acoustic wave determined by the period of the electrode fingers of the IDT electrode 10. The acoustic wave resonator 2 includes the second piezoelectric layer having Euler Angles (ψ2, θ2, φ2), and the IDT electrode 20 disposed on the second piezoelectric layer. ψ2 is [(greater than or equal to 85° and less than or equal to 95°)+180°×n], θ2 is [(greater than or equal to 85° and less than or equal to 95°)+180°×n], and φ2 is [(greater than or equal to −40° and less than or equal to 20°)+180°×n]. The acoustic wave resonator 1 and the acoustic wave resonator 2 are implemented as a single chip.

The above-mentioned configuration allows the acoustic wave resonator 1 to utilize the S0 mode, which is a high acoustic velocity mode, as its principal mode, and allows the acoustic wave resonator 2 to utilize the SH0 mode, which is a low acoustic velocity mode, as its principal mode. The acoustic wave resonators 1 and 2 are electrically connected and implemented as a single chip. This makes it possible to provide the acoustic wave device 100 that is compact and has a wide resonant frequency band.

In one example, the acoustic wave device 100 is configured such that (t/λ1)×d is equal to or greater than about 8.94 (g/m³), for example, where t is the film thickness of the electrode fingers of the IDT electrode 10, and d is the density of the IDT electrode 10.

According to the above-mentioned configuration, in the acoustic wave resonator 1, leakage of an acoustic wave of the S0 mode toward the support substrate 34 can be reduced even when the piezoelectric layer 31 of an X-cut type is used.

In one example, the acoustic wave device 100 is configured such that the IDT electrode 10 includes platinum (Pt).

According to the above-mentioned configuration, the IDT electrode 10 includes a high density metal. This makes it possible to reduce leakage of an acoustic wave of the so mode toward the support substrate 34 even when the piezoelectric layer 31 of an X-cut type is used.

In one example, the acoustic wave device 100 is configured such that the first piezoelectric layer and the second piezoelectric layer define the piezoelectric layer 31 that is a single common piezoelectric layer in which ψ1=ψ2 and θ1=θ2; the piezoelectric layer 31 includes the major surfaces 31a and 31b that are opposite to each other, the IDT electrodes 10 and 20 are disposed on the major surface 31a, and the acoustic wave device 100 further includes the support substrate 34 that is a common substrate disposed at the same side of the acoustic wave device 100 as the major surface 31b of the piezoelectric layer 31, and a common dielectric layer between the piezoelectric layer 31 and the support substrate 34.

According to the above-mentioned configuration, the acoustic wave device 100 includes the piezoelectric layer 31, the common dielectric layer, and the support substrate 34 that are common to the acoustic wave resonators 1 and 2. This makes it possible to provide the acoustic wave device 100 that is compact.

In one example, the acoustic wave device 100 is configured such that the common dielectric layer includes the low acoustic velocity layer 32 and the high acoustic velocity layer 33 that are disposed in a direction from the piezoelectric layer 31 toward the support substrate 34, the acoustic velocity of a bulk wave in the low acoustic velocity layer 32 is lower than the acoustic velocity of a bulk wave in each of the piezoelectric layer 31 and the support substrate 34, and the acoustic velocity of a bulk wave in the high acoustic velocity layer 33 is higher than the acoustic velocity of the bulk wave in the low acoustic velocity layer 32.

The above-mentioned configuration makes it possible to reduce leakage, toward the support substrate 34, of an acoustic wave propagating in the piezoelectric layer 31.

In one example, the acoustic wave device 100 is configured such that the low acoustic velocity layer 32 has a thickness greater than about 0.15×λ1 and less than about 0.25×λ1, and the high acoustic velocity layer 33 has a thickness greater than about 0.15×λ1 and less than about λ1, for example.

The above-mentioned configuration makes it possible to reduce spurious signals of unwanted modes appearing at frequencies higher than the resonant frequency band of the acoustic wave resonator 1, and reduce spurious signals of unwanted modes appearing at frequencies lower than the resonant frequency band of the acoustic wave resonator 2.

In one example, the acoustic wave device 100 and 100A further include the insulating layer 41 that covers the IDT electrodes 10 and 20.

The above-mentioned configuration makes it possible to reduce spurious signals resulting from the resonances of acoustic waves other than the acoustic wave of the principal mode.

In one example, the acoustic wave device 100A according to Modification 2 is configured such that the piezoelectric layer 311 has Euler angles (ψ1, θ1, φ1), and includes the major surfaces 311a and 311b that are opposite to each other, the IDT electrode 10 is disposed on the major surface 311a, and the acoustic wave resonator 1A further includes the support substrate 34 disposed at the same side of the acoustic wave device 100A as the major surface 311b of the piezoelectric layer 311, and the first dielectric layer between the piezoelectric layer 311 and the support substrate 34.

The above-mentioned configuration allows the acoustic wave resonator 1A to utilize the S0 mode, which is a high acoustic velocity mode, as its principal mode.

In one example, the acoustic wave device 100A is configured such that the first dielectric layer includes the low acoustic velocity layer and the high acoustic velocity layer that are disposed in a direction from the piezoelectric layer 311 toward the support substrate 34, the acoustic velocity of a bulk wave in the low acoustic velocity layer is lower than the acoustic velocity of a bulk wave in each of the piezoelectric layer 311 and the support substrate 34, and the acoustic velocity of a bulk wave in the high acoustic velocity layer is higher than the acoustic velocity of the bulk wave in the low acoustic velocity layer.

In one example, the acoustic wave device 100A is configured such that the piezoelectric layer 312 has Euler angles (ψ2, θ2, φ2), and includes the major surfaces 312a and 312b that are opposite to each other, the IDT electrode 20 is disposed on the major surface 312a, and the acoustic wave resonator 2A further includes the support substrate 34 disposed at the same side of the acoustic wave device 100A as the major surface 312b of the piezoelectric layer 312, and the second dielectric layer between the piezoelectric layer 312 and the support substrate 34.

The above-mentioned configuration allows the acoustic wave resonator 2A to utilize the SH0 mode, which is a low acoustic velocity mode, as its principal mode.

In one example, the acoustic wave device 100A is configured such that the second dielectric layer includes the low acoustic velocity layer and the high acoustic velocity layer that are disposed in a direction from the piezoelectric layer 312 toward the support substrate 34, the acoustic velocity of a bulk wave in the low acoustic velocity layer is lower than the acoustic velocity of a bulk wave in each of the piezoelectric layer 312 and the support substrate 34, and the acoustic velocity of a bulk wave in the high acoustic velocity layer is higher than the acoustic velocity of the bulk wave in the low acoustic velocity layer.

In one example, the acoustic wave devices 100 and 100A are configured such that 1 is [(greater than or equal to 85° and less than or equal to 95°)+180°×n], θ1 is [(greater than or equal to 85° and less than or equal to 95°)+180°×n], and φ1 is [(greater than or equal to 50° and less than or equal to 70°)+180°×n]; and ψ2 is [(greater than or equal to 85° and less than or equal to 95°)+180°×n], θ2 is [(greater than or equal to 85° and less than or equal to 95°)+180°×n], and φ2 is [(greater than or equal to −40° and less than or equal to 0°)+180°×n].

According to the above-mentioned configuration, setting the third Euler angle φ1 to be [(greater than or equal to 50° and less than or equal to 70°)+180°×n] allows the acoustic wave resonator 1 to have a large signal strength ratio between the S0 mode, which is its principal mode, and the SH0 mode. Further, setting the third Euler angle φ2 to be [(greater than or equal to −40° and less than or equal to 0°)+180°×n] allows the acoustic wave resonator 2 to have a large signal strength ratio between the SH0 mode, which is its principal mode, and the S0 mode.

In one example, the acoustic wave device 100 (100A) is configured such that the acoustic wave resonator 1 (1A) utilizes the so mode as its principal mode, and the acoustic wave resonator 2 (2A) utilizes the SH0 mode as its principal mode.

The above-mentioned configuration makes it possible to provide the acoustic wave device 100 (100A) having a wide resonant frequency band.

In one example, the acoustic wave filter 200 according to the present example embodiment includes the input/output terminals 201 and 202, the series resonators 211 to 217 disposed in a series path that connects the input/output terminals 201 and 202, and the shunt resonators 221 to 224 connected between the series path and ground. At least one of the series resonators 211 to 217 is the acoustic wave resonator 1 (1A). At least one of the shunt resonators 221 to 224 is the acoustic wave resonator 2 (2A). The series resonators 211 to 217 and the shunt resonators 221 to 224 each include the piezoelectric layer 31 that is a common piezoelectric layer.

The above-mentioned configuration allows each of the series resonators 211 to 217 to utilize the so mode, which is a high acoustic velocity mode, as its principal mode, and allows each of the shunt resonators 221 to 224 to utilize the SH0 mode, which is a low acoustic velocity mode, as its principal mode. Further, the series resonators 211 to 217 and the shunt resonators 221 to 224 are electrically connected and implemented as a single chip. This makes it possible to provide the acoustic wave filter 200 that is compact and has a wide passband.

Although the acoustic wave devices and the acoustic wave filters according to example embodiments of the present invention have been described above with reference to the example embodiments and modifications thereof, the present invention is not limited to the example embodiments and the modifications mentioned above. The present invention is intended to also encompass other example embodiments achieved by combining any components in the example embodiments and the modifications mentioned above, as well as modifications attained by modifying the example embodiments and the modifications mentioned above in various ways that may become apparent to those skilled in the art without departing from the spirit and scope of the present invention.

Example embodiments of the present invention are applicable to a wide variety of communication devices such as mobile phones, as acoustic wave devices and acoustic wave filters that are disposed in the front-end section of such communication devices.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising
a first acoustic wave resonator and a second acoustic wave resonator electrically connected to each other; wherein
the first acoustic wave resonator includes:
a first piezoelectric layer having Euler angles (ψ1, θ1, φ1); and
a first interdigital transducer (IDT) electrode on the first piezoelectric layer;
ψ1 is [(greater than or equal to 85° and less than or equal to 95°)+180°×n (n being an integer)], θ1 is [(greater than or equal to 85° and less than or equal to 95°)+180°×n], and φ1 is [(greater than or equal to 30° and less than or equal to 140°)+180°×n]; and
the first piezoelectric layer has a thickness less than or equal to 1×λ1, where λ1 is a wavelength of an acoustic wave determined by a period of electrode fingers of the first IDT electrode;
the second acoustic wave resonator includes:
a second piezoelectric layer having Euler angles (ψ2, θ2, φ2); and
a second IDT electrode on the second piezoelectric layer;
ψ2 is [(greater than or equal to 85° and less than or equal to 95°)+180°×n], θ2 is [(greater than or equal to 85° and less than or equal to 95°)+180°×n], and φ2 is [(greater than or equal to −40° and less than or equal to 20°)+180°×n]; and
the first acoustic wave resonator and the second acoustic wave resonator are implemented as a single chip.

2. The acoustic wave device according to claim 1, wherein (t/λ1)×d is equal to or greater than about 8.94 (g/m³), where t is a film thickness of the electrode fingers of the first IDT electrode, and d is a density of the first IDT electrode.

3. The acoustic wave device according to claim 2, wherein the first IDT electrode includes platinum.

4. The acoustic wave device according to claim 1, wherein
the first piezoelectric layer and the second piezoelectric layer are defined by a single common piezoelectric layer in which ψ1=ψ2 and θ1=θ2;
the common piezoelectric layer includes a first major surface and a second major surface that are opposite from each other;
the first IDT electrode and the second IDT electrode are on the first major surface; and
the acoustic wave device further comprises
a common support substrate at a same side of the acoustic wave device as the second major surface of the common piezoelectric layer; and
a common dielectric layer between the common piezoelectric layer and the common support substrate.

5. The acoustic wave device according to claim 4, wherein
the common dielectric layer includes a first common dielectric film and a second common dielectric film extending in a direction from the common piezoelectric layer toward the common support substrate;
an acoustic velocity of a bulk wave in the first common dielectric film is lower than an acoustic velocity of a bulk wave in each of the common piezoelectric layer and the common support substrate; and
an acoustic velocity of a bulk wave in the second common dielectric film is higher than the acoustic velocity of the bulk wave in the first common dielectric film.

6. The acoustic wave device according to claim 5, wherein
the first common dielectric film has a film thickness greater than about 0.15×λ1 and less than 0.25×λ1, and
the second common dielectric film has a film thickness greater than about 0.15×λ1 and less than 1×λ1.

7. The acoustic wave device according to claim 1, further comprising an insulating layer that covers the first IDT electrode and the second IDT electrode.

8. The acoustic wave device according to claim 1, wherein
the first piezoelectric layer includes a third major surface and a fourth major surface that are opposite to each other;
the first IDT electrode is on the third major surface; and
the first acoustic wave resonator further includes:
a first support substrate at a same side of the acoustic wave device as the fourth major surface of the first piezoelectric layer; and
a first dielectric layer between the first piezoelectric layer and the first support substrate.

9. The acoustic wave device according to claim 8, wherein the first dielectric layer includes a first dielectric film and a second dielectric film that extend in a direction from the first piezoelectric layer toward the first support substrate;
an acoustic velocity of a bulk wave in the first dielectric film is lower than an acoustic velocity of a bulk wave in each of the first piezoelectric layer and the first support substrate; and
an acoustic velocity of a bulk wave in the second dielectric film is higher than the acoustic velocity of the bulk wave in the first dielectric film.

10. The acoustic wave device according to claim 1, wherein
the second piezoelectric layer includes a fifth major surface and a sixth major surface that are opposite to each other;
the second IDT electrode is on the fifth major surface; and
the second acoustic wave resonator further includes:
a second support substrate at a same side of the acoustic wave device as the sixth major surface of the second piezoelectric layer; and
a second dielectric layer between the second piezoelectric layer and the second support substrate.

11. The acoustic wave device according to claim 10, wherein
the second dielectric layer includes a third dielectric film and a fourth dielectric film that extend in a direction from the second piezoelectric layer toward the second support substrate;
an acoustic velocity of a bulk wave in the third dielectric film is lower than an acoustic velocity of a bulk wave in each of the second piezoelectric layer and the second support substrate; and
an acoustic velocity of a bulk wave in the fourth dielectric film is higher than the acoustic velocity of the bulk wave in the third dielectric film.

12. The acoustic wave device according to claim 1, wherein
ψ1 is [(greater than or equal to 85° and less than or equal to 95°)+180°×n], θ1 is [(greater than or equal to 85° and less than or equal to 95°)+180°×n], and φ1 is [(greater than or equal to 50° and less than or equal to 70°)+180°×n]; and
ψ2 is [(greater than or equal to 85° and less than or equal to 95°)+180°×n], θ2 is [(greater than or equal to 85° and less than or equal to 95°)+180°×n], and φ2 is [(greater than or equal to −40° and less than or equal to 0°)+180°×n].

13. The acoustic wave device according to claim 1, wherein
the first acoustic wave resonator is configured to use an S0 mode as a principal mode; and
the second acoustic wave resonator is configured to use an SH0 mode as a principal mode.

14. An acoustic wave filter comprising:
a first input/output terminal and a second input/output terminal;
one or more series resonators along a path that connects the first input/output terminal and the second input/output terminal; and
one or more shunt resonators connected between the one or more series resonators and ground; wherein
at least one of the one or more series resonators is the first acoustic wave resonator and at least one of the one or more shunt resonators is the second acoustic wave resonator according to claim 4.

15. The acoustic wave filter according to claim 14, wherein
the common dielectric layer includes a first common dielectric film and a second common dielectric film extending in a direction from the common piezoelectric layer toward the common support substrate;
an acoustic velocity of a bulk wave in the first common dielectric film is lower than an acoustic velocity of a bulk wave in each of the common piezoelectric layer and the common support substrate; and
an acoustic velocity of a bulk wave in the second common dielectric film is higher than the acoustic velocity of the bulk wave in the first common dielectric film.

16. The acoustic wave filter according to claim 15, wherein
the first common dielectric film has a film thickness greater than about 0.15×λ1 and less than 0.25×λ1, and the second common dielectric film has a film thickness greater than about 0.15×λ1 and less than 1×λ1.

17. The acoustic wave filter according to claim 14, further comprising an insulating layer that covers the first IDT electrode and the second IDT electrode.

18. The acoustic wave filter according to claim 14, wherein
the first piezoelectric layer includes a third major surface and a fourth major surface that are opposite to each other;
the first IDT electrode is on the third major surface; and
the first acoustic wave resonator further includes:
a first support substrate at a same side of the acoustic wave device as the fourth major surface of the first piezoelectric layer; and
a first dielectric layer between the first piezoelectric layer and the first support substrate.

19. The acoustic wave filter according to claim 18, wherein the first dielectric layer includes a first dielectric film and a second dielectric film that extend in a direction from the first piezoelectric layer toward the first support substrate;
an acoustic velocity of a bulk wave in the first dielectric film is lower than an acoustic velocity of a bulk wave in each of the first piezoelectric layer and the first support substrate; and
an acoustic velocity of a bulk wave in the second dielectric film is higher than the acoustic velocity of the bulk wave in the first dielectric film.

20. The acoustic wave filter according to claim 14, wherein
the second piezoelectric layer includes a fifth major surface and a sixth major surface that are opposite to each other;
the second IDT electrode is on the fifth major surface; and
the second acoustic wave resonator further includes:
a second support substrate at a same side of the acoustic wave device as the sixth major surface of the second piezoelectric layer; and
a second dielectric layer between the second piezoelectric layer and the second support substrate.
